(19) United States
(12) Patent Application Publication
(10) Pub. No.: US 2024/0222515 A1
(43) Pub. Date: Jul. 4, 2024

(54) SEMICONDUCTOR DEVICE INCLUDING OXIDE SEMICONDUCTOR LAYER AND ELECTRONIC DEVICE INCLUDING THE SEMICONDUCTOR DEVICE

(71) Applicant: Samsung Electronics Co., Ltd., Suwon-si (KR)

(72) Inventors: Jeeeun YANG, Suwon-si (KR); Yongsung KIM, Suwon-si (KR); Sangwook KIM, Suwon-si (KR); Kwanghee LEE, Suwon-si (KR); Moonil JUNG, Suwon-si (KR)

(73) Assignee: Samsung Electronics Co., Ltd., Suwon-si (KR)

(21) Appl. No.: 18/398,912

(22) Filed: Dec. 28, 2023

(30) Foreign Application Priority Data
Dec. 30, 2022 (KR) 10-2022-0191108

(51) Int. Cl. H01L 29/786; H01L 29/423; H10B 10/00

(52) U.S. Cl. CPC H01L 29/7869; H01L 29/42392; H10B 10/12

(57) ABSTRACT

Provided are a semiconductor device including an oxide semiconductor layer and an electronic device including the semiconductor device. The semiconductor device includes a substrate, a first electrode provided on the substrate, a second electrode provided on the first electrode, an oxide semiconductor layer provided between the first electrode and the second electrode, a gate electrode provided in a thickness direction of the oxide semiconductor layer, and a gate insulating layer provided between the oxide semiconductor layer and the gate electrode, wherein a measurement density relative to a theoretical density of the oxide semiconductor layer is about 90% or more. The oxide semiconductor layer of the semiconductor device may have a more uniform and improved film density, and may improve the reliability of the device due to the improved film density.

### CROSS-REFERENCE TO RELATED APPLICATION

This application is based on and claims priority under 35 U.S.C. § 119 to Korean Patent Application No. 10-2022-0191108, filed on Dec. 30, 2022, in the Korean Intellectual Property Office, the disclosure of which is incorporated by reference herein in its entirety.

### BACKGROUND

### 1. Field

The disclosure relates to a semiconductor device including an oxide semiconductor layer and an electronic device including the semiconductor device.

### 2. Description of the Related Art

A transistor is a semiconductor device that serves as an electrical switching device and is used in various integrated circuit devices including memory, a driving integrated circuit (IC), a logic device, and/or the like. In order to increase the integration of integrated circuit devices, the space occupied by transistors arranged thereon is rapidly shrinking, and research is being conducted to reduce the size of transistors while maintaining their performance.

Oxide semiconductor devices have been studied for years as transparent semiconductor materials with a wide bandgap of 3.0 eV or more. Oxide semiconductor devices are materials that are mass-produced as driving devices for large-area organic light emitting diode (OLED) TVs.

As semiconductor processes becomes finer, the size of transistors has been decreased, and the area where the gate electrode and the channel contact each other has been decreased too, thereby causing problems due to a short channel effect. For example, phenomena such as threshold voltage variation, carrier velocity saturation, and degradation of the subthreshold characteristics may occur. Accordingly, a method of overcoming a short channel effect and reducing an off-current is needed.

### SUMMARY

Provided are a semiconductor device including an oxide semiconductor layer and an electronic device including the semiconductor device.

Additional aspects will be set forth in part in the description which follows and, in part, will be apparent from the description, or may be learned by practice of the presented embodiments of the disclosure.

According to an aspect of at least one embodiment, a semiconductor device includes a first electrode, a second electrode, an oxide semiconductor layer between the first electrode and the second electrode, a gate electrode spaced apart from the oxide semiconductor layer, and a gate insulating layer insulating the oxide semiconductor layer from the gate electrode, wherein a measurement density of the oxide semiconductor layer is about 90% or more of a theoretical density of the oxide semiconductor layer.

The measurement density of the oxide semiconductor layer may be greater than the theoretical density.

The thickness of the oxide semiconductor layer may be within a range of 1 nm to 10 nm.

The oxide semiconductor layer may include an oxide of at least one of In, Zn, Sn, Ga, or Hf.

The oxide semiconductor layer may include at least one of InGaZnO, ZrInZnO, InGaZnO₄, ZnInO, In₂O₃, or HfInZnO.

The oxide semiconductor layer may include In, Ga, and Zn, and the content of the In in the oxide semiconductor layer may be greater than or equal to at least one of a content of the Ga or a content of the Zn.

In, Ga, and Zn included in the oxide semiconductor layer may be X:Y:Z (1≤X≤7, 1≤Y≤3, and 1≤Z≤3), respectively.

A substrate may be further included, and a longitudinal direction of the oxide semiconductor layer may be parallel to a thickness direction of the substrate.

An oxide mixture of indium, gallium, and zinc may be on the surface of the oxide semiconductor layer.

Each of the oxide semiconductor layer, the gate insulating layer, and the gate electrode may be in line such that a longitudinal direction thereof is perpendicular to a surface of the substrate, and the oxide semiconductor layer, the gate insulating layer, and the gate electrode are arranged in a horizontal direction with respect to the surface of the substrate.

The first electrode, the second electrode, and the oxide semiconductor layer may have the same width.

The gate electrode may be thicker than the gate insulating layer.

The oxide semiconductor layer may be rod-shaped, the gate insulating layer may surround the oxide semiconductor layer, and the gate electrode may surround the gate insulating layer.

The first electrode may include at least one of W, Co, Ni, Fe, Ti, Mo, Cr, Zr, Hf, Nb, Ta, Ag, Au, Al, Cu, Sb, V, Ru, Pt, Zn, or Mg.

An oxide isolation layer may be adjacent to the gate electrode, the gate insulating layer, and the oxide semiconductor layer.

According to another aspect of at least one embodiment, an electronic device includes a plurality of memory cells, wherein each of the memory cells includes a switching element, and a data storage element connected to the switching element, wherein the switching element includes a first electrode, a second electrode, an oxide semiconductor layer between the first electrode and the second electrode, a gate electrode spaced apart from the oxide semiconductor layer, and a gate insulating layer insulating the oxide semiconductor layer from the gate electrode, wherein a measurement density of the oxide semiconductor layer is 90% or more of a theoretical density of the oxide semiconductor layer.

The measurement density of the oxide semiconductor layer may be greater than the theoretical density.

The oxide semiconductor layer may include In, Ga, and Zn, and a content of the In in the oxide semiconductor layer is greater than or equal to at least one of a content of the Ga or a content of the Zn.

The In, Ga, and Zn included in the oxide semiconductor layer may be represented by X:Y:Z (5≤X≤7, 1≤Y≤3, and 1≤Z≤3), respectively.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 illustrates a semiconductor device according to at least one embodiment;

FIG. 2 illustrates a semiconductor device according to at least one embodiment;

FIG. 3 illustrates a semiconductor device according to at least one embodiment;

FIGS. 4A to 4C are diagrams and a graph illustrating a deposition state of a precursor according to a method of manufacturing a semiconductor device according to at least one embodiment;

FIGS. 5A to 5G are diagrams illustrating a method of manufacturing a semiconductor device according to at least one embodiment;

FIG. 6 is a schematic block diagram of a display driver IC (DDI) including a semiconductor device and a display device including the DDI according to at least one embodiment;

FIG. 7 is a circuit diagram of a complementary metal-oxide semiconductor (CMOS) inverter including a semiconductor device according to at least one embodiment;

FIG. 8 is a circuit diagram of a CMOS static random-access memory (SRAM) device including a semiconductor device according to at least one embodiment;

FIG. 9 is a circuit diagram of a CMOS NAND circuit including a semiconductor device according to an exemplary embodiment;

FIG. 10 is a block diagram of an electronic system including a semiconductor device according to at least one embodiment; and

FIG. 11 is a block diagram of an electronic system including a semiconductor device according to at least one embodiment.

### DETAILED DESCRIPTION

Reference will now be made in detail to embodiments, examples of which are illustrated in the accompanying drawings. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments will be described in detail with reference to the accompanying drawings. In the following drawings, the same reference numerals refer to the same components, and the size of each component in the drawings may be exaggerated for clarity and convenience of description. Meanwhile, embodiments described below are merely illustrative, and various modifications are possible from these embodiments.

Hereinafter, the term “upper portion” or “on” may also include “to be present on the top, bottom, left or right portion on a non-contact basis” as well as “to be present just on the top, bottom, left or right portion in directly contact with” unless expressly indicated otherwise. For example, it will be understood that such spatially relative terms are intended to encompass different orientations of the device in use or operation in addition to the orientation depicted in the figures, and that the device may be otherwise oriented (rotated 90 degrees or at other orientations) and the spatially relative terms used herein interpreted accordingly. Singular expressions include plural expressions unless the context clearly means otherwise. In addition, when a part “contains” a component, this means that it may contain other components, rather than excluding other components, unless otherwise stated. When the terms “about” or “substantially” are used in this specification in connection with a numerical value, it is intended that the associated numerical value includes a manufacturing tolerance (e.g., ±10%) around the stated numerical value. Further, regardless of whether numerical values are modified as “about” or “substantially,” it will be understood that these values should be construed as including a manufacturing or operational tolerance (e.g., ±10%) around the stated numerical values. When referring to “C to D”, this means C inclusive to D inclusive unless otherwise specified.

The use of the term “the” and similar indicative terms may correspond to both singular and plural. Unless there is clear order or contrary description of the steps constituting the method, these steps may be performed in the appropriate order, and are not necessarily limited to the order described.

Functional elements described herein using the terms “controller”, “unit”, or the like mean a unit that processes at least one function or operation, which may be implemented in processing circuitry such as hardware, software, and/or a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc., and/or electronic circuits including said components. For example, the processing circuitry may include electrical components such as logic gates including at least one of AND gates, OR gates, NAND gates, NOT gates, etc., and/or electronic circuits including said components.

The terms first, second, etc. may be used to describe various components, but the components should not be limited by terms. Terms are used only for the purpose of distinguishing one component from another. When there is an explicit description of the order of operations of the method or there is no description contrary thereto, these operations may be performed in an appropriate order and the order is not necessarily limited to the described order.

The connection or connection members of lines between the components shown in the drawings represent functional connection and/or physical or circuit connections, and may be replaceable or represented as various additional functional connections, physical connections, and/or circuit connections in an actual device.

The use of all examples or illustrative terms is simply to describe technical ideas in detail, and the scope is not limited due to these examples or illustrative terms unless the scope is limited by the claims.

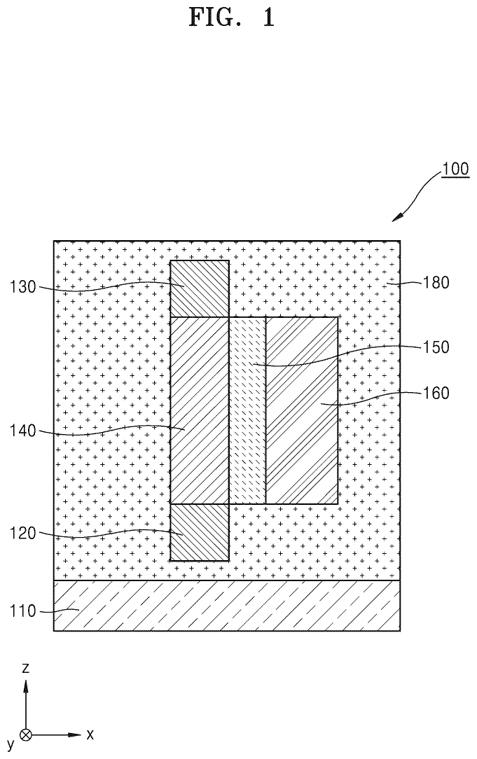

FIG. 1 illustrates a semiconductor device according to at least one embodiment.

Referring to FIG. 1, the semiconductor device 100 may include a substrate 110, a first electrode 120 arranged on the substrate, a second electrode 130 spaced apart from the first electrode 120, an oxide semiconductor layer 140 arranged between the first electrode 120 and the second electrode 130, a gate electrode 160 spaced apart from the oxide semiconductor layer 140, and a gate insulating layer 150 arranged between the oxide semiconductor layer 140 and the gate electrode 160.

The oxide semiconductor layer 140 according to at least one embodiment is an oxide including at least one selected from the group consisting of indium (In), gallium (Ga), tin (Sn), hafnium (Hf), and zinc (Zn), and may be used as a channel layer. The channel layer may be included in various semiconductor devices including a field effect transistor (FET).

The substrate 110 may be an insulating substrate, a semiconductor substrate, and/or may be a semiconductor substrate having an insulating layer formed on the surface thereof. The semiconductor substrate may include, for example, at least one of Si, Ge, SiGe, or a group Ill-V semiconductor material. The substrate 110 may be, for example, a silicon substrate on which silicon oxide is formed on a surface thereof, but is not limited thereto.

The first electrode 120 may include an electrically conductive material such as a metal material and/or a metallic material. For example, the first electrode 120 may include at least of tungsten (W), cobalt (Co), nickel (Ni), iron (Fe), titanium (Ti), molybdenum (Mo), chromium (Cr), zirconium (Zr), hafnium (Hf), niobium (Nb), tantalum (Ta), silver (Ag), gold (Au), aluminum (Al), copper (Cu), tin (Sn), vanadium (V), ruthenium (Ru), platinum (Pt), zinc (Zn), and/or magnesium (Mg). The first electrode 120 may be arranged to be spaced apart from the substrate 110, but is not limited to being necessarily arranged to be spaced apart from the substrate 110. The first electrode 120 may be arranged as a lower electrode of a vertical channel transistor (VCT) structure including a vertical channel region. The second electrode 130 may include an electrically conductive material such a metal material and/or a metallic material. For example, in at least one embodiment, the material of the second electrode 130 is the same as that of the first electrode 120. In addition, the first electrode 120 and the second electrode 130 may be vertically spaced apart from each other, and the second electrode 130 may be arranged as an upper electrode of the vertical channel transistor (VCT) structure.

The first electrode 120 and the second electrode 130 may be arranged in a direction crossing the upper surface of the substrate 110. For example, the first electrode 120 and the second electrode 130 may be arranged to be spaced apart in a vertical direction (e.g., the Z direction) perpendicular to the upper surface of the substrate 110. In at least one embodiment, first electrode 120, the oxide semiconductor layer 140, and the second electrode 130 may be arranged in a line in the direction crossing the surface of the substrate 110, for example, in the vertical direction (Z direction) perpendicular to the surface of the substrate. In at least one embodiment, the first electrode 120, the oxide semiconductor layer 140, and the second electrode 130 may be sequentially arranged without intervention of other layers. The first electrode 120, the oxide semiconductor layer 140, and the second electrode 130 may have the same thickness when viewed in cross-section. For example, side surfaces of first electrode 120, the oxide semiconductor layer 140, and the second electrode may be planar (and/or substantially planar) when viewed in cross-section. The first electrode 120 may be a lower electrode of the VCT structure, and the second electrode 130 may be an upper electrode of the VCT structure, respectively, but are not limited thereto.

When the semiconductor device 100 according to at least one embodiment has a vertical channel transistor (VCT) structure including a vertical channel region, the oxide semiconductor layer 140, the gate insulating layer 150, and the gate electrode 160 may form a stack such that the respective longitudinal directions of the oxide semiconductor layer 140, the gate insulating layer 150, and the gate electrode 160 face extend in a direction crossing the surface of the substrate 110, and may be arranged horizontally with respect to the surface of the substrate 110. In at least one embodiment, the VCT may be supported by an insulator, such as an encapsulant 180 and/or a scaffold, but the examples are not limited thereto.

In at least one embodiment, the oxide semiconductor layer 140 may be arranged such that the longitudinal direction is a direction crossing the surface of the substrate 110, for example, a direction (Z direction) perpendicular to the surface of the substrate 110. In the present specification, the longitudinal direction refers to a direction in which the length of the corresponding component is long when viewed in cross-section, as illustrated in the drawing. In the present specification, the “longitudinal direction” means the longitudinal direction of the corresponding oxide semiconductor layer, unless expressly indicated otherwise.

In at least one embodiment, the longitudinal direction may be a direction (Z direction) perpendicular to the surface of the substrate 110. For example, the longitudinal direction of the oxide semiconductor layer 140 may be arranged perpendicular to the thickness direction of the substrate.

The first electrode 120 and the second electrode 130 may be sequentially arranged from the surface of the substrate 110 in the longitudinal direction of the oxide semiconductor layer 140.

The thickness direction (unidirectional) of the oxide semiconductor layer 140 may mean a direction parallel to the surface of the substrate 110. The oxide semiconductor layer 140, the gate insulating layer 150, and the gate electrode 160 may be sequentially arranged in a thickness direction (unidirectional) of the oxide semiconductor layer 140.

For example, in at least one embodiment, the gate electrode 160 may be arranged on one side of the oxide semiconductor layer 140. The gate insulating layer 150 may be arranged between the oxide semiconductor layer 140 and the gate electrode 160. The gate electrode 160 may be arranged such that the length direction (Z direction) of the gate electrode 160 is perpendicular to the surface of the substrate 110. The oxide semiconductor layer 140, the gate insulating layer 150, and the gate electrode 160 may be arranged in a line in a horizontal direction (X direction) with respect to the surface of the substrate 110.

The oxide semiconductor layer 140 may include a material selected from the group consisting of InGaZnO, ZrInZnO, InGaZnO₄, ZnInO, In₂O₃, HfInZnO, and/or combinations thereof. In at least some embodiments, the material is a transparent semiconductor, and in these cases the oxide semiconductor layer 140 may be referred to as a transparent semiconductor layer.

The content of indium (In) of the oxide semiconductor layer 140 may be greater than or equal to the content of gallium or zinc, but is not limited thereto.

In, Ga, and Zn included in the oxide semiconductor layer 140 may be mixed in a predetermined (or otherwise determined) ratio, and may be represented by X:Y:Z (1≤X≤7, 0≤Y≤3, and 0≤Z≤3) and/or (1≤X≤7, 1≤Y≤3, and 1≤Z≤3), respectively. However, the embodiments are not limited thereto, and the indium content may be variously changed in a range greater than or equal to the gallium or zinc content.

For example, the oxide semiconductor layer 140 may be an indium-containing oxide including a dopant of at least one of Zn, Sn, Ga, and Hf. The oxide semiconductor layer 140 may include zinc indium oxide (ZIO), indium gallium oxide (IGO), and/or indium gallium zinc oxide (IGZO). In at least one embodiment, the oxide semiconductor layer 140 includes In and Zn, and the content of In in the oxide semiconductor layer 140 may be greater than or equal to the content of Zn of the oxide semiconductor layer 140.

In at least one embodiment, the oxide semiconductor layer 140 may include (In)_{b1}(Zn)_{b2}(M³)b₃O. Here, M³ is Sn, Ga, Hf, or any combination thereof, b1 may be a real number satisfying 1≤b1≤10, b2 may be a real number satisfying 0≤b2≤7, b3 may be a real number satisfying 0≤b3≤7, and b1>b2.

The oxide semiconductor layer 140 according to at least one embodiment may have an actual measurement density with respect to a theoretical density of about 88% or more, about 90% or more, about 92% or more, about 95% or more, about 100% or more, or about 105% or more. In addition, the oxide semiconductor layer 140 may have an actual measurement density with respect to the theoretical density of 120% or less, 115% or less, or 110% or less. For example, the actual measurement density of the oxide semiconductor layer 140 may be greater than the calculated theoretical density.

The theoretical density may be a value of the density calculated from the theoretical density of the oxide of the element excluding oxygen in each component of the oxide semiconductor layer. For example, when the oxide semiconductor layer contains In—Ga—Zn—O, indium oxide, gallium oxide, and zinc oxide, excluding oxygen among indium, gallium, zinc, and oxygen, which are respective constituent elements, may be used to calculate a theoretical density. The atomic and/or mass ratios of indium oxide, gallium oxide, and zinc oxide may be calculated from the elemental analysis values (at % or mass %) of indium, gallium, and zinc in the oxide semiconductor layer, and the theoretical density may be calculated from the calculated mass ratios.

The theoretical density may be calculated when the oxide semiconductor layer is crystalline. The theoretical density of a material with a crystal structure=(the number of atoms in a unit crystal×atomic weight)/(lattice volume×Avogadro's number).

Specifically, the theoretical density may be calculated by determining a comparative crystal structure of a composition ratio of an oxide such as IGZO, and in consideration of the composition, including the number of atoms, lattice size, and Avogadro's number by obtaining the size of the unit lattice and the number of atoms belonging to the unit lattice from the oxide's crystal structure.

The measurement density of the oxide semiconductor layer may be measured by devices such as RBS or X-ray Reflectometry (XRR) The above-described measurement density range in accordance with at least one embodiment may be measured using a Rutherford Backscattering Spectroscopy (RBS) device. However, the embodiments are not necessarily limited thereto.

The measurement density of the oxide semiconductor layer according to at least one embodiment may be about 6.0 g/cm³ or more and 9.0 g/cm³ or less. The deviation of the measurement density in the oxide semiconductor layer may be about 3% or less, about 5% or less, about 7% or less, or about 10% or less.

When the oxide semiconductor layer includes In—Ga—O having a composition ratio of In:Ga=about 2.4:1, the theoretical density of the oxide semiconductor layer may be about 6.9 g/cm³ or more and 7.1 g/cm³ or less, and the actual measurement density of the oxide semiconductor layer may be about 6.3 g/cm³ or more and 7.7 g/cm³ or less, specifically, about 6.7 g/cm³ or more and 6.9 g/cm³ or less.

When the oxide semiconductor layer includes In—Ga—Zn—O having a composition ratio of In:Ga:Zn=about 1:1:1, the theoretical density of the oxide semiconductor layer may be about 6.0 g/cm³ or more to about 6.3 g/cm³ or less. For example, the theoretical density of InGaZnO₄ may be 6.12 g/cm³. The actual measurement density of the oxide semiconductor layer may be about 5.4 g/cm³ or more to about 6.9 g/cm³ or less, specifically, about 5.7 g/cm³ or more to about 6.0 g/cm³ or less.

When the oxide semiconductor layer includes In—Ga—Zn—O having a composition ratio of In:Ga:Zn=about 2:2:1, the theoretical density of the oxide semiconductor layer may be about 6.4 g/cm³ or more to about 6.6 g/cm³ or less. For example, the theoretical density of In₂Ga₂ZnO₇ may be 6.5 g/cm³. The actual measurement density of the oxide semiconductor layer may be about 6.0 g/cm³ or more to about 7.0 g/cm³ or less, specifically, about 6.2 g/cm³ or more to about 6.7 g/cm³ or less.

The thickness of the oxide semiconductor layer 140 may be about 1 nm or more to about 10 nm or less, but is not limited thereto.

The gate electrode 160 may be arranged on the oxide semiconductor layer 140 while being arranged between the first electrode 120 and the second electrode 130 in the longitudinal direction. The gate electrode 160, the first electrode 120, and the second electrode 130 may be arranged on the same surface as that of the oxide semiconductor layer 140. According to at least one embodiment, the gate electrode 160 may include an electrically conductive material. For example, the gate electrode 160 may include a metal material and/or a metallic material.

The gate insulating layer 150 may be arranged between the oxide semiconductor layer 140 and the gate electrode 160 to electrically disconnect (insulate) the oxide semiconductor layer 140 with the gate electrode 160. In at least one embodiment, the gate insulating layer 150 may include a ferroelectric material. For example, the ferroelectric material may include at least one of an oxide ferroelectric material, a polymer ferroelectric material, a fluoride ferroelectric material such as BaMgF₄ (BMF), and/or a ferroelectric semiconductor material.

The gate electrode 160 may be thicker than the gate insulating layer 150. The thickness of the gate electrode 160 may be about 10 nm or more, and the thickness of the gate insulating layer 150 may be about 7 nm or less. However, the embodiments are not necessarily limited thereto.

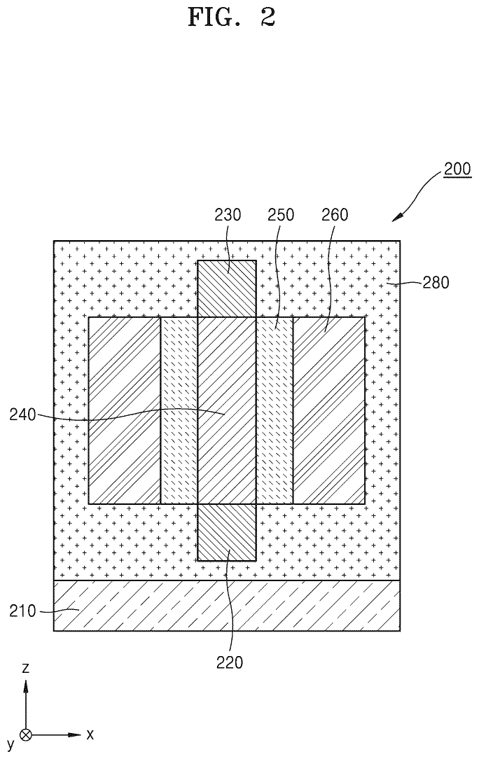

FIG. 2 illustrates a semiconductor device according to at least one embodiment.

In FIG. 2, components using the similar reference numbers as in FIG. 1 have substantially the same configurations and functional effects as those described in FIG. 1, and thus the detailed description thereof will be omitted.

A semiconductor device 200 includes a first electrode 220, a second electrode 230, and an oxide semiconductor layer 240 arranged in a direction (Z direction) perpendicular to the surface of a substrate 210. A gate insulating layer 250 may be arranged around the oxide semiconductor layer 240, and a gate electrode 260 may be arranged around the gate insulating layer 250. The gate electrode 260 may be arranged around the oxide semiconductor layer 240 to increase an area in which the gate electrode 260 and the oxide semiconductor layer 240 face each other, and to improve a short channel effect.

For example, in at least one embodiment, the oxide semiconductor layer 240 may have a rod shape, and the gate insulating layer 250 may be formed to surround a side surface of the oxide semiconductor layer 240, and the gate electrode 260 may be formed to surround a side surface of the gate insulating layer 250. For example, in at least one embodiment, the oxide semiconductor layer 240 may be referred to as penetrating the gate electrode 260.

The semiconductor device 200 having such a structure is referred to as a gate all around (GAA) structure. In a semiconductor device having a GAA structure, an area in which a channel layer and a gate electrode contact each other is larger than that of a conventional planar structure, thereby contributing to an improvement in performance of the device.

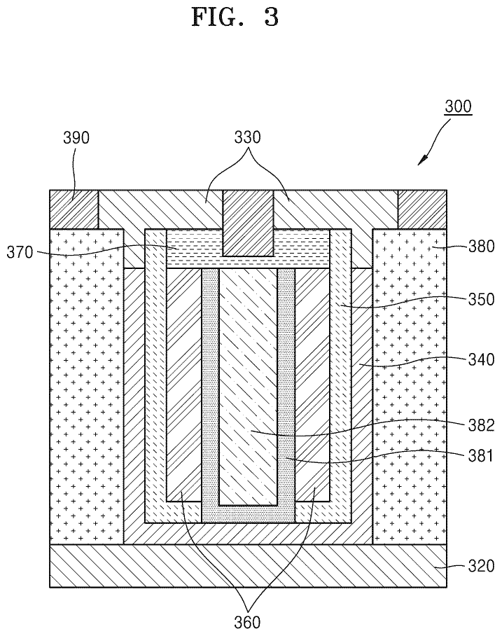

FIG. 3 illustrates a semiconductor device according to at least one embodiment.

In FIG. 3, components using the similar reference numbers as in FIG. 1 have substantially the same configurations and functional effects as those described in FIG. 1, and thus the detailed description thereof will be omitted.

Referring to FIG. 3, provided is a semiconductor device 300 including an oxide semiconductor layer 340 arranged between a first electrode 320 and a second electrode 330, a gate insulating layer 350, and a gate electrode 360.

A oxide isolation layer 370 may be provided to isolate the gate electrode 360 from other material layers. The oxide isolation layer 370 may include oxides and other materials, and is not limited to any particular material. An insulating layer 390 may be provided to fill empty spaces and/or to provide additional structural support.

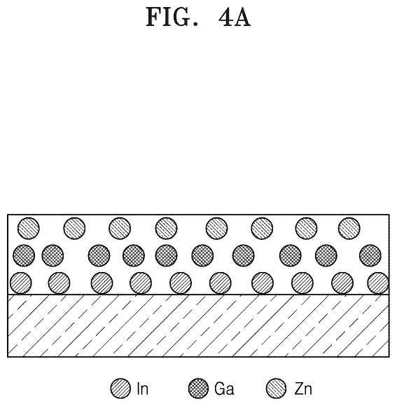

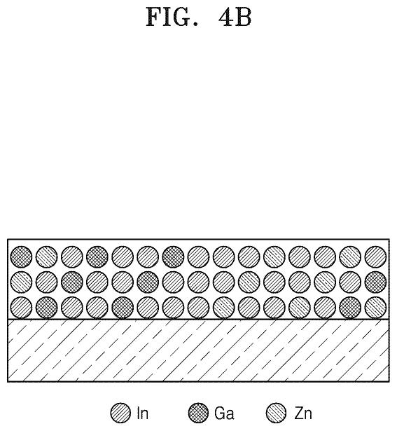

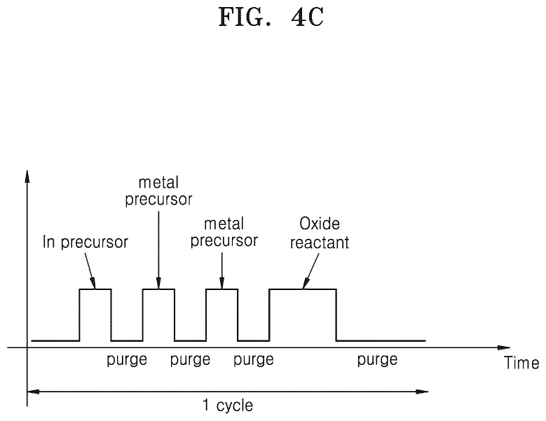

FIGS. 4A to 4C are diagrams and a graph illustrating a deposition state of a precursor according to a method of manufacturing a semiconductor device according to at least one embodiment.

FIG. 4A is a diagram related to a method of forming an oxide semiconductor layer of InGaZnO as a comparative example. The oxide semiconductor layer may be generally formed by an atomic layer deposition (ALD) process. When the oxide semiconductor layer is InGaZnO, an oxidizing agent is introduced after an indium precursor is introduced, and thus indium is oxidized to form an indium oxide film. In addition, after a gallium precursor is introduced, an oxidizing agent is introduced to perform an oxidation reaction of gallium, thereby forming a gallium oxide film on the indium oxide film. Next, after a zinc precursor is introduced, an oxidizing agent is introduced and zinc is oxidized to form a zinc oxide film on the gallium oxide film, which may form an oxide semiconductor layer as shown in FIG. 4A.

When the oxide semiconductor layer according to the comparative example is composed of three films, the same oxide may be arranged according to the same film, and different oxides may be arranged on different films adjacent to each other. Thus, since different metals are unlikely to share oxygen, the density of the oxide semiconductor layer may be less. In addition, different oxides are formed according to the thickness of the oxide semiconductor layer, and thus the density deviation of the oxide semiconductor layer may be great.

The oxide semiconductor layer according to at least one embodiment may be formed by oxidizing a plurality of precursors all at once without oxidizing each precursor.

FIG. 4B is a diagram related to a method of forming an oxide semiconductor layer of InGaZnO according to at least one embodiment.

FIG. 4C is a graph illustrating, over time, an order of metal precursors input to an oxide semiconductor layer according to at least one embodiment.

Referring to FIGS. 4B and 4C, a metal precursor deposition state using an ascorbate controlled atomic layer deposition (AC-ALD) process is illustrated. Indium, gallium, and zinc are deposited as metal precursors to form a stack structure. More metal precursors per unit area or volume may be stacked compared to FIG. 4A.

When the oxide semiconductor layer is InGaZnO, the oxide semiconductor layers of FIGS. 4B and 4C may introduce an indium precursor, a gallium precursor, and a zinc precursor and then oxidize the indium precursor, the gallium precursor, and the zinc precursor all at once. The oxide semiconductor layer may be performed as a unit cycle by performing a process of injecting and purging a plurality of metal precursors, reacting with an oxide reactant, and then purging the same. Oxide reactants may include, for example, O₃.

When the InGaZnO film of the at least one embodiment is formed, indium precursors may be uniformly distributed by introducing the indium precursors first. Thus, the conductivity of the film may be improved.

Referring to FIG. 4C, a gallium precursor and a zinc precursor may be introduced in this order after introduction of the indium precursor. However, the embodiments are not limited thereto. After the indium precursor is introduced, the zinc precursor and the gallium precursor may be introduced in this order, or the zinc precursor and the gallium precursor may be simultaneously introduced. Alternatively, after the introduction of the indium precursor, a precursor having a large atomic size may be introduced earlier than a precursor having a small atomic size. The order of the metal precursor introduced after the introduction of the indium precursor may be determined by various factors to be described below including a growth rate per cycle (GPC) value of the metal precursor. The cycle is as described above.

The oxide semiconductor layer shown in FIG. 4B may have a thickness in the same range as that of FIG. 4A by forming a plurality of InGaZnO layers. The oxide semiconductor layer according to at least one embodiment may have improved electrical conductivity because indium is uniformly distributed not only in the same film but also in the thickness direction. In addition, a plurality of metal oxides may be placed on the same film to increase the density compared to a single metal oxide, and different metals may share oxygen in the same film, so the measurement density of the metal oxide may be greater than the theoretical density. The plurality of metal oxides are arranged for each film unit, so that the density deviation according to the thickness may be less.

The indium (In) precursor is introduced into the reactor before other precursors because when the content of indium is high, the conductivity of the channel material may be improved and further the performance of the semiconductor device may be improved.

The higher the content of the indium precursor, the better the conductivity of the channel material, so the indium precursor may be introduced into the reactor before other metal precursors and/or at a greater rate than the other precursors. The oxide material including In, Ga, and Zn is arranged simultaneously adjacent to the source electrode or drain electrode and the oxide semiconductor layer. Among them, in the contact surface (interface) between the channel material and the source electrode or the drain electrode, the performance of the semiconductor device may be improved when the resistance between both materials is low. Therefore, a high indium content may be required to reduce resistance between the channel and the source electrode and/or drain electrode, and to this end, in at least some embodiments, the indium content may be increased on the contact surface (interface) between the electrode and the channel, and the indium precursor may be introduced into the reactor before other metal precursors.

The input order of the introduced precursor may be determined by considering a growth rate cycle per unit cycle (GPC) value. For example, if the GPC value when Zn is added after Ga is first added, is greater than that when Zn is first added and then Ga is added, Ga may be added first.

Specifically, determining the precursor to be introduced after the indium precursor is introduced may be determined according to a deposition rate per unit time for each metal precursor.

The indium oxide, the gallium oxide, and the zinc oxide mixed and present on the surface of the oxide semiconductor layer may be deposited to different thicknesses in accordance with a unit deposition cycle.

As the value of the thickness of the thin film of the metal precursor deposited per unit deposition cycle is increased, it may mean that the reaction speed of the metal precursor introduced into the reactor is faster. That is, it may mean that the reaction rate of the metal precursor having a higher GPC value is faster.

Depending on the different GPC values, an order of the metal precursor introduced into the reactor may be determined, and an order of the metal precursor introduced next may be determined according to a type of the metal precursor introduced in a cycle immediately before a predetermined (or otherwise determined) metal precursor to be introduced.

However, while a predetermined (or otherwise determined) metal precursor oxide is deposited on the surface of the oxide semiconductor layer, impurities such as carbon, hydrogen, and nitrogen may be contained. The type of impurities is not necessarily limited to the above description and may include various impurities.

Before forming an oxide of the metal precursor earlier introduced into the reactor, another metal precursor is introduced into the reactor again. In this manner, In—Ga—Zn may be made in a state in which a plurality of metal precursors are mixed in the reactor instead of the form of an oxide single film, and then an oxidizing agent may be introduced to react with the metal precursors all at once. Indium oxide, gallium oxide, and zinc oxide may be mixed on the surface of the oxide semiconductor layer. In this type of deposition, oxide semiconductors in a uniform and spatially dense form may be formed. For example, since material deposition becomes uniform, a density deviation between regions of the oxide semiconductor layer may be less.

Here, the density deviation may mean a difference in the degree of material deposition for each region of the material layer including a plurality of materials. The density deviation may decrease as a plurality of materials are uniformly deposited in one material layer, and on the contrary, the density deviation may increase as a plurality of materials are non-uniformly deposited in one material layer.

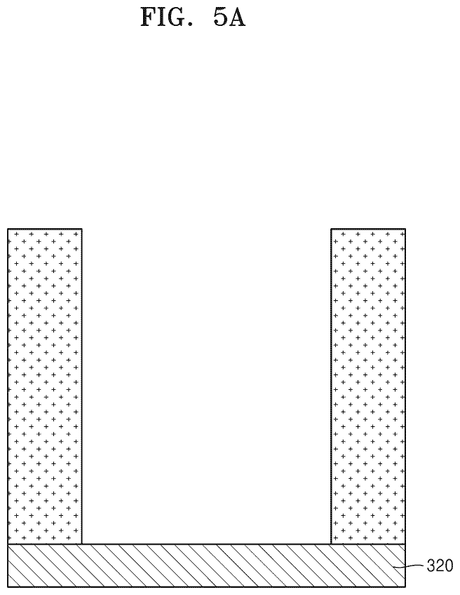

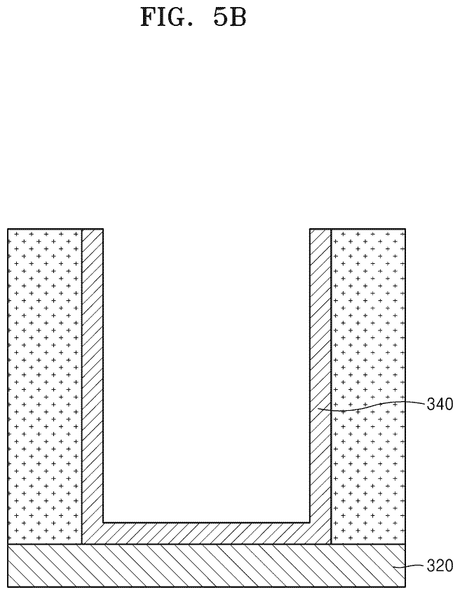

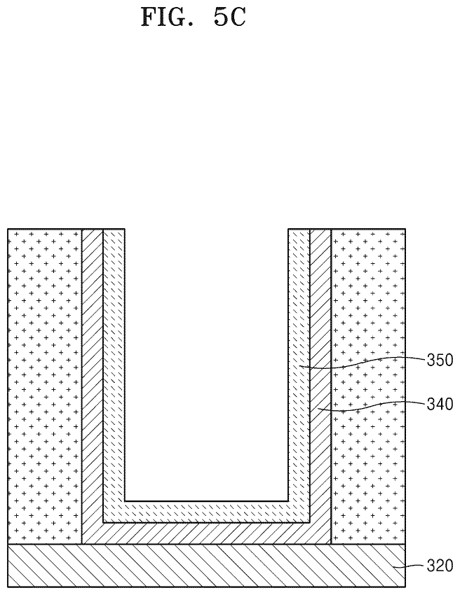

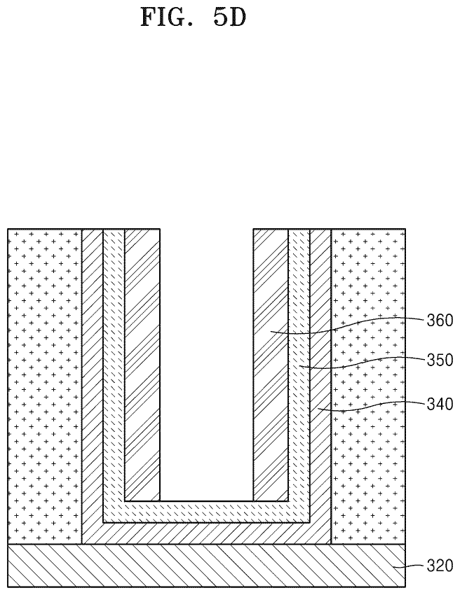

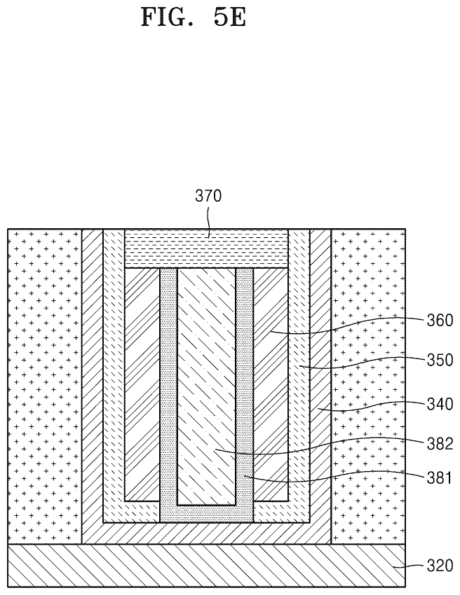

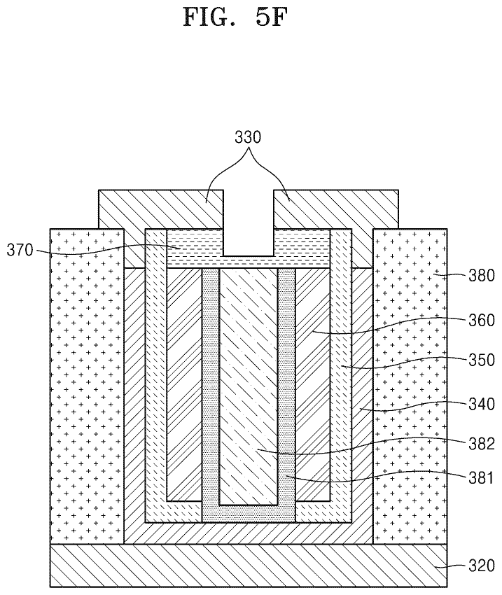

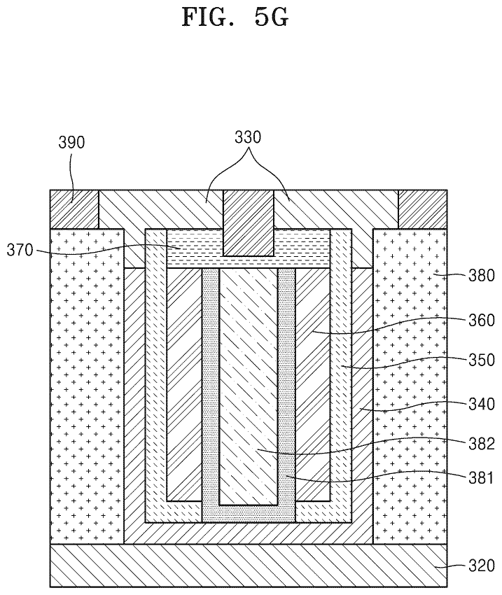

FIGS. 5A to 5G are diagrams illustrating a method of manufacturing a semiconductor device according to at least one embodiment. Referring to FIG. 5A, a first electrode 320 is provided. As described above, the first electrode 320 may include a metal or metallic material. For example, the first electrode 320 may include at least one of tungsten (W), cobalt (Co), nickel (Ni), iron (Fe), titanium (Ti), molybdenum (Mo), chromium (Cr), zirconium (Zr), hafnium (Hf), niobium (Nb), tantalum (Ta), silver (Ag), gold (Au), aluminum (Al), copper (Cu), tin (Sn), vanadium (V), ruthenium (Ru), platinum (Pt), zinc (Zn), and/or magnesium (Mg). The first electrode 320 may be arranged to be spaced apart from the substrate 110 (e.g., as illustrated in FIG. 1), but is not limited to being necessarily arranged to be spaced apart from the substrate 110 (FIG. 1). The first electrode 320 may be arranged as a lower electrode having a vertical channel transistor (VCT) structure including a vertical channel region. In at least one embodiment, an insulator may be deposited on the first electrode 320 and patterned to include a trench. In at least one embodiment, e.g., as illustrated in FIG. 1, an insulator may be an upper region of the substrate 110 and/or deposited on the substrate 110, and the first electrode 320 may be arranged in the trench.

Referring to FIG. 5B, an oxide semiconductor layer 340 may be formed on the first electrode 320. The oxide semiconductor layer 340 may be deposited through sputtering, thermal ALD, or physical ALD (PE-ALD), but is not limited thereto.

As described above, the oxide semiconductor layer 340 of FIG. 5B may be an indium-containing oxide including at least one of Zn, Sn, Ga, and Hf, and may be present by mixing In, Ga, and Zn on the surface of the oxide semiconductor layer 340. The oxide semiconductor layer 340 may include zinc indium oxide (ZIO), indium gallium oxide (IGO), or indium gallium zinc oxide (IGZO). The oxide semiconductor layer 340 may include a material selected from the group consisting of InGaZnO, ZrInZnO, InGaZnO₄, ZnInO, In₂O₃, HfInZnO, and/or combinations thereof. The oxide semiconductor layer 340 includes In and Zn, and the content of In in the oxide semiconductor layer 340 may be greater than or equal to the content of Zn of the oxide semiconductor layer 340. Referring to FIG. 5C, a gate insulating layer 350 may be deposited on the oxide semiconductor layer 340. The gate insulating layer 350 may be deposited through ALD, sputtering, and/or the like.

Referring to FIG. 5D, a gate electrode 360 may be deposited on the gate insulating layer 350. The gate electrode 360 may be deposited through ALD, and/or sputtering. The material or configuration of the gate electrode 360 is the same as described above with reference to FIGS. 1 and 3.

Referring to FIG. 5E, An insulating liner (381) may be positioned between a plurality of spaced-apart gate electrodes (360). The insulating liner (381) can be conformally arranged on the upper surface of the sidewalls and/or the oxide semiconductor layer (340) of the gate electrodes (360) facing each other. The insulating liner (381) can have a top surface disposed in the same plane as the plurality of gate electrodes (360). The insulating liner (381) may include, for example, silicon nitride. A buried insulating layer (382) can fill the space between the plurality of spaced-apart gate electrodes (360) on the insulating liner (381). The buried insulating layer (382) may include, for example, silicon oxide.

Additionally, an oxide isolation layer 370 adjacent to the gate electrode 360, the gate insulating layer 350, and the oxide semiconductor layer 340 may be formed. The oxide isolation layer 370 includes a material selected to isolate gate electrode from other material layers, and may include an oxide and/or an etch selective material.

Referring to FIG. 5F, a second electrode 330 may be additionally formed. The first electrode 320 and the second electrode 330 may include the same material as that described in FIG. 1, and may be an upper electrode or a lower electrode having a VCT structure as described in FIG. 1, but are not limited thereto.

Referring to FIG. 5G, an insulating layer 390 may be additionally deposited in an empty space of the semiconductor device 300. The insulating layer may be provided on the substrate to fill the empty space. The first electrode 320 may be provided to be spaced apart from the substrate by an insulating layer. The description of each component is as described above.

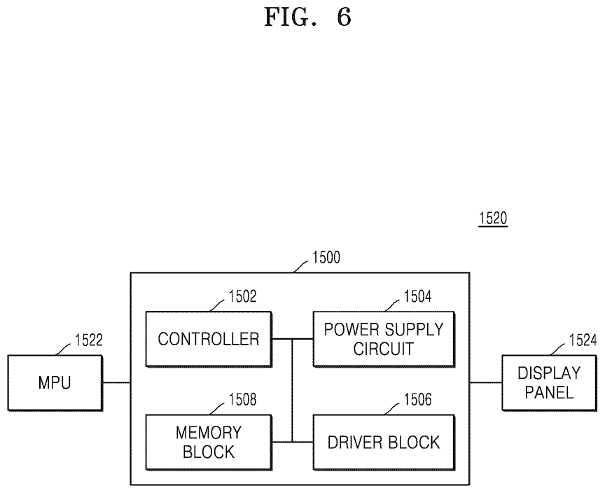

FIG. 6 is a schematic block diagram of a display driver IC (DDI) 1500 including a semiconductor device and a display device 1520 including the DDI 1500 according to at least one embodiment.

Referring to FIG. 6, the DDI 1500 may include a controller 1502, a power supply circuit unit 1504, a driver block 1506, and a memory block 1508. The controller 1502 receives and decodes a command applied from the main processing unit (MPU) 1522, and controls each of blocks of the DDI 1500 to implement an operation according to the command. The power supply circuit unit 1504 generates a driving voltage in response to the control of the controller 1502. The driver block 1506 drives the display panel 1524 using the driving voltage generated by the power supply circuit unit 1504 in response to the control of the controller 1502. The display panel 1524 may be a liquid crystal display panel, a micro LED device, and/or the like. The memory block 1508 is a block that temporarily stores commands input to the controller 1502 or control signals output from the controller 1502, or stores necessary data, and may include memories such as RAM and ROM. The power supply circuit unit 1504 and the driver block 1506 may include the semiconductor devices according to the embodiments described above with reference to FIGS. 1 to 3.

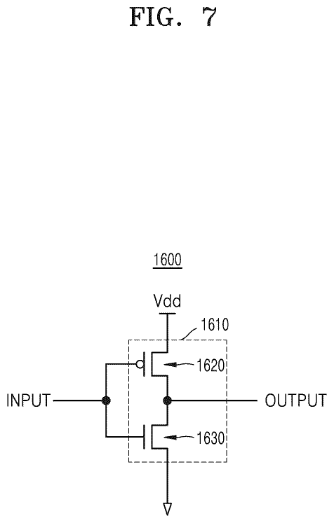

FIG. 7 is a circuit diagram of a complementary metal-oxide semiconductor (CMOS) inverter according to at least one embodiment.

The CMOS inverter 1600 includes a CMOS transistor 1610. The CMOS transistor 1610 includes a p-type metal-oxide-semiconductor (PMOS) transistor 1620 and an n-type MOS (NMOS) transistor 1630 connected between a power terminal Vdd and a ground terminal. At least one of the PMOS transistor 1620 and/or the NMOS transistor 1630 may include the semiconductor device according to the embodiments described above with reference to FIGS. 1 to 3.

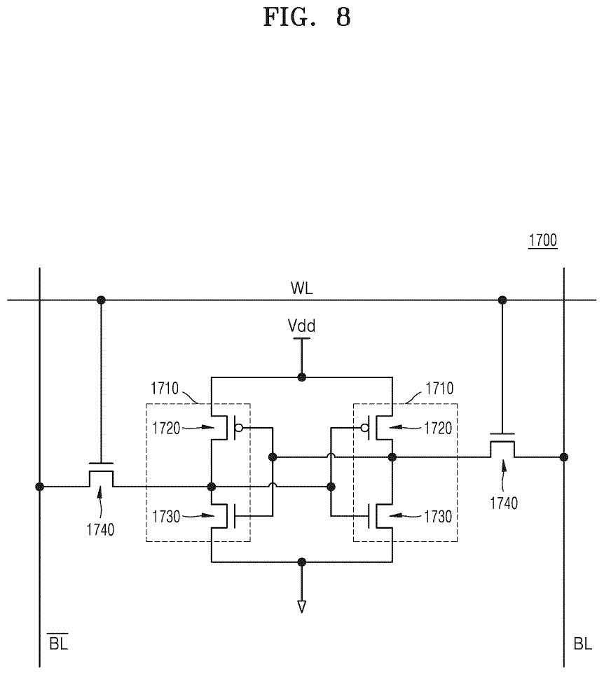

FIG. 8 is a circuit diagram of a CMOS static random-access memory (SRAM) device 1700 according to at least one embodiment.

The CMOS SRAM device 1700 includes a pair of driving transistors 1710. Each of the pair of driving transistors 1710 includes a PMOS transistor 1720 and an NMOS transistor 1730 connected between the power terminal Vdd and the ground terminal. The CMOS SRAM device 1700 may further include a pair of transmission transistors 1740. Sources of the transmission transistor 1740 are cross-connected to common nodes of the PMOS transistor 1720 and the NMOS transistor 1730 constituting the driving transistor 1710. A power terminal Vdd is connected to a source of the PMOS transistor 1720, and a ground terminal is connected to a source of the NMOS transistor 1730. A word line WL may be connected to a gate of each of a pair of transmission transistors 1740, and a bit line BL and an inverted bit line may be connected to a drain of each of the pair of transmission transistors 740.

At least one of the driving transistor 1710 and the transmission transistor 1740 of the CMOS SRAM device 1700 may include the semiconductor device according to at least one embodiments described above with reference to FIGS. 1 to 3.

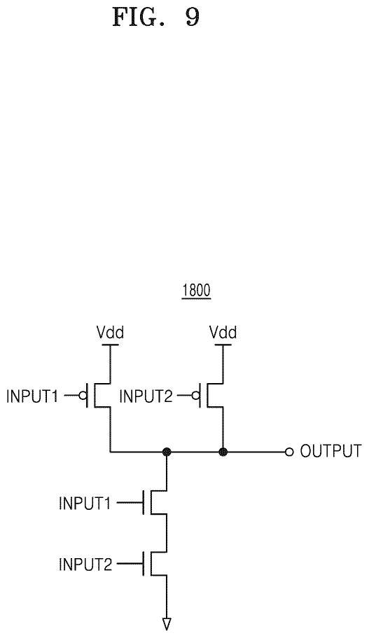

FIG. 9 is a circuit diagram of a CMOS NAND circuit 1800 according to at least one embodiment.

The CMOS NAND circuit 1800 includes a pair of CMOS transistors through which different input signals are transmitted. The CMOS NAND circuit 1800 may include the semiconductor device according to the embodiments described above with reference to FIGS. 1 to 3.

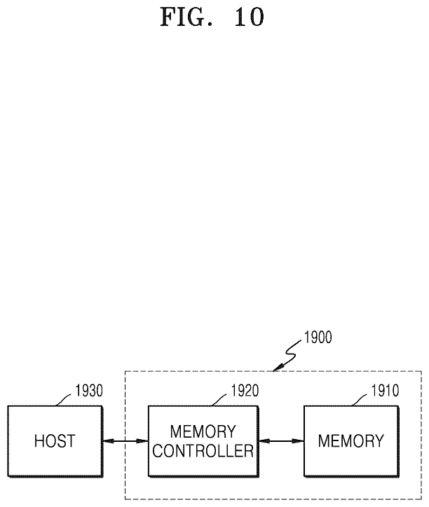

FIG. 10 is a block diagram illustrating an electronic system 1900 according to at least one embodiment.

The electronic system 1900 includes a memory 1910 and a memory controller 1920. The memory controller 1920 may control the memory 1910 to read data from the memory 1910 and/or write data to the memory 1910 in response to a request from the host 1930. At least one of the memory 1910 and the memory controller 1920 may include the semiconductor device according to the embodiments described above with reference to FIGS. 1 to 3.

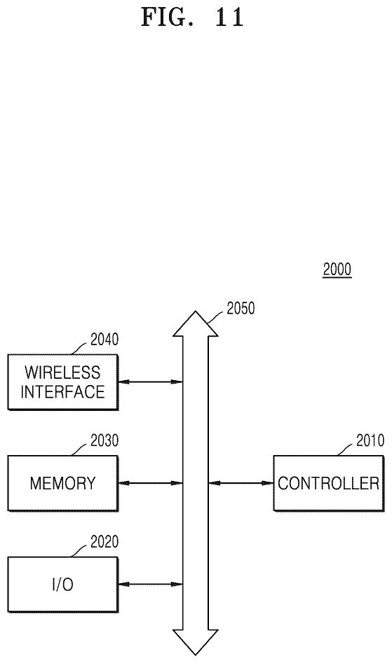

FIG. 11 is a block diagram of an electronic system 2000 according to at least one embodiment.

The electronic system 2000 may configure a wireless communication device, or an apparatus capable of transmitting and/or receiving information under a wireless environment. The electronic system 2000 includes a controller 2010, an input/output device (I/O) 2020, a memory 2030, and a wireless interface 2040 which are interconnected through a bus 2050, respectively.

The controller 2010 may include at least one of a microprocessor, a digital signal processor, or a processing device similar thereto. The input/output device 2020 may include at least one of a keypad, a keyboard, and a display. The memory 2030 may be used to store commands to be executed by the controller 2010. For example, the memory 2030 may be used to store user data. The electronic system 2000 may use the wireless interface 2040 to transmit/receive data through a wireless communication network. The wireless interface 2040 may include an antenna and/or a wireless transceiver. The electronic system 1000 may include the semiconductor device according to the embodiments described above with reference to FIGS. 1 to 3.

In the semiconductor device according to some embodiments, the oxide semiconductor layer of the disclosed semiconductor device may have a more uniform and improved film density, and the reliability of the semiconductor device may be improved by utilizing the improved film density.

However, the effects of the inventive concepts are not limited to the above disclosure.

The semiconductor device according to the embodiments may exhibit good electrical performance in a micro-structure, and thus may be applied to an integrated circuit device, and may implement miniaturization, low power, and high performance.

The semiconductor device, the method of manufacturing the semiconductor device, and the electronic device including the semiconductor device have been described with reference to the embodiments shown in the drawings, but these are only examples, and those of ordinary skill in the art will understand that various modifications and equivalent other embodiments are possible.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a first electrode;
a second electrode;
an oxide semiconductor layer between the first electrode and the second electrode;
a gate electrode spaced apart from the oxide semiconductor layer; and
a gate insulating layer insulating the oxide semiconductor layer from the gate electrode,
wherein a measurement density of the oxide semiconductor layer is about 90% or more of a theoretical density of the oxide semiconductor layer.

2. The semiconductor device of claim 1, wherein the measurement density of the oxide semiconductor layer is greater than the theoretical density.

3. The semiconductor device of claim 1, wherein a thickness of the oxide semiconductor layer is within a range of about 1 nm to about 10 nm.

4. The semiconductor device of claim 1, wherein the oxide semiconductor layer comprises an oxide of at least one of In, Zn, Sn, Ga, or Hf.

5. The semiconductor device of claim 1, wherein the oxide semiconductor layer comprises at least one of InGaZnO, ZrInZnO, InGaZnO₄, ZnInO, In₂O₃, or HfInZnO.

6. The semiconductor device of claim 1, wherein
the oxide semiconductor layer comprises In, Ga, and Zn, and
a content of the In in the oxide semiconductor layer is greater than or equal to at least one of a content of the Ga or a content of the Zn.

7. The semiconductor device of claim 1, wherein
the oxide semiconductor layer comprises In, Ga, and Zn, and
the In, the Ga, and the Zn included in the oxide semiconductor layer is represented by X:Y:Z (1≤X≤7, 1≤Y≤3, and 1≤Z≤3), respectively.

8. The semiconductor device of claim 1, further comprising:
a substrate,
wherein a longitudinal direction of the oxide semiconductor layer is parallel to a thickness direction of the substrate.

9. The semiconductor device of claim 8, wherein each of the oxide semiconductor layer, the gate insulating layer, and the gate electrode are in line such that the oxide semiconductor layer, the gate insulating layer, and the gate electrode are stacked in a horizontal direction with respect to the surface of the substrate and the longitudinal direction of the oxide semiconductor layer, a longitudinal direction of the gate insulating layer, and a longitudinal direction of the gate electrode are perpendicular to a surface of the substrate.

10. The semiconductor device of claim 1, wherein a surface of the oxide semiconductor layer includes an oxide mixture of indium, gallium, and zinc.

11. The semiconductor device of claim 1, wherein the first electrode, the second electrode, and the oxide semiconductor layer have the same thickness when viewed in cross-section.

12. The semiconductor device of claim 1, wherein, when viewed in cross-section, the gate electrode is thicker than the gate insulating layer.

13. The semiconductor device of claim 1, wherein
the oxide semiconductor layer is rod-shaped,
the gate insulating layer surrounds the oxide semiconductor layer, and
the gate electrode surrounds the gate insulating layer.

14. The semiconductor device of claim 1, wherein the first electrode comprises at least one of W, Co, Ni, Fe, Ti, Mo, Cr, Zr, Hf, Nb, Ta, Ag, Au, Al, Cu, Sb, V, Ru, Pt, Zn, or Mg.

15. The semiconductor device of claim 1, further comprising:
an oxide isolation layer adjacent to the gate electrode, the gate insulating layer, and the oxide semiconductor layer.

16. An electronic device comprising:
a plurality of memory cells,
wherein each of the memory cells comprises
a switching element, and
a data storage element connected to the switching element,
wherein the switching element comprises
a first electrode,
a second electrode,
an oxide semiconductor layer between the first electrode and the second electrode;
a gate electrode spaced apart from the oxide semiconductor layer; and
a gate insulating layer insulating the oxide semiconductor layer from the gate electrode,
wherein a measurement density of the oxide semiconductor layer is about 90% or more of a theoretical density of the oxide semiconductor layer.

17. The electronic device of claim 16, wherein the measurement density of the oxide semiconductor layer is greater than the theoretical density.

18. The electronic device of claim 16, wherein
the oxide semiconductor layer comprises In, Ga, and Zn, and
a content of the In in the oxide semiconductor layer is greater than or equal to at least one of a content of the Ga or a content of the Zn.

19. The electronic device of claim 16, wherein
the oxide semiconductor layer comprises In, Ga, and Zn, and
the In, the Ga, and the Zn included in the oxide semiconductor layer is represented by X:Y:Z (1≤X≤7, 1≤Y≤3, and 1≤Z≤3), respectively.
